(19) United States
(12) Patent Application Publication
(10) Pub. No.: US 2026/0248027 A1
(43) Pub. Date: Aug. 20, 2026

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Tzu-Yin MA, Taichung City (TW); Rung-Jeng LIN, Taichung City (TW); Meng-Han TSAI, Taichung City (TW)

(73) Assignee: SILICONWARE PRECISION INDUSTRIES CO., LTD., Taichung City (TW)

(21) Appl. No.: 19/170,690

(22) Filed: Apr. 4, 2025

(30) Foreign Application Priority Data
Feb. 17, 2025 (TW) 114105754

(51) Int. Cl. H01L 23/31; H01L 21/48; H01L 21/56; H01L 23/00; H01L 23/29; H01L 23/498; H01L 23/538; H01L 25/03; H01L 25/065

(52) U.S. Cl. CPC H10W 74/121; H10W 70/093; H10W 70/611; H10W 74/01; H10W 74/117; H10W 74/40; H10W 90/00; H10W 90/401; H10W 70/65; H10W 74/00; H10W 90/701; H10W 90/724

(57) ABSTRACT

An electronic package and a manufacturing method thereof are provided, in which at least one first electronic element is provided, a first packaging operation is performed to form a first encapsulation layer to encapsulate the first electronic element, a second packaging operation is performed to form a second encapsulation layer to encapsulate the first encapsulation layer, and a contraction direction of the second encapsulation layer is opposite to a warping direction of the first encapsulation layer, such that the structural warping problems caused by the contraction of conventional packaging adhesive are resolved.

### BACKGROUND

### 1. Technical Field

The present disclosure relates to a semiconductor packaging technology, and more particularly, to an electronic package and a manufacturing method thereof.

### 2. Description of Related Art

With the evolution of semiconductor packaging technology, different packaging types of semiconductor devices have been developed. In order to improve electrical performance and save packaging space, the industry has developed a packaging type which stacks multiple package structures to form a package-on-package (PoP) structure. In this packaging type, the heterogeneous integration characteristics of the system-in-package (SiP) allow for the integration of electronic elements with different functions, such as memory, central processing unit, graphics processor, and image application processor, into the system through a stacking design, making it suitable for various thin, light, and compact electronic products.

FIG. 1 is a schematic cross-sectional view of a conventional package-on-package structure 1. The package-on-package structure 1 includes a packaging adhesive 15, a semiconductor chip 11 embedded in the packaging adhesive 15, a circuit structure 10 and a routing structure 14 disposed on opposite sides of the packaging adhesive 15, and a plurality of conductive pillars 13 embedded in the packaging adhesive 15 and electrically connected to the circuit structure 10 and the routing structure 14. The semiconductor chip 11 is electrically connected to the circuit structure 10 via a plurality of conductors 112, and a plurality of solder balls 16 are formed on a lower side of the circuit structure 10, so that the package-on-package structure 1 is connected to a circuit board (not shown) via the solder balls 16.

However, the aforementioned package-on-package structure often warps due to material contraction when the packaging adhesive is formed. Excessive warpage can result in poor operability in subsequent processes. For example, subsequent process equipment may fail to operate automatically, requiring manual handling or outsourcing, which introduces risks to quality and workplace safety. Further, the warpage caused by material contraction affects the warpage morphology (smiling face or frown face) of the final package-on-package structure. In other words, the edges of the package-on-package structure may bend upward or downward, leading to issues like solder ball non-wetting at the interface of the final package-on-package structure, thereby causing reliability problems in consumer products.

Therefore, there is a need for a solution that addresses the aforementioned shortcomings in the prior art.

### SUMMARY

In view of the aforementioned shortcomings of the prior art, the present disclosure provides an electronic package, which comprises: a first encapsulation layer; at least one first electronic element embedded in the first encapsulation layer; and a second encapsulation layer encapsulating the first encapsulation layer, wherein a contraction direction of the second encapsulation layer is opposite to a warping direction of the first encapsulation layer.

The present disclosure also provides a method of manufacturing an electronic package, the method comprises: providing at least one first electronic element; performing a first packaging operation to form a first encapsulation layer to encapsulate the at least one first electronic element; and performing a second packaging operation to form a second encapsulation layer to encapsulate the first encapsulation layer, wherein a contraction direction of the second encapsulation layer is opposite to a warping direction of the first encapsulation layer.

In the aforementioned electronic package and method, the present disclosure further comprises: forming a first circuit structure on one side of the first encapsulation layer.

In the aforementioned electronic package and method, the present disclosure further comprises: forming a second circuit structure on the other side of the first encapsulation layer.

In the aforementioned electronic package and method, the present disclosure further comprises: forming a plurality of conductive pillars electrically connected to the first circuit structure and the second circuit structure in the first encapsulation layer.

In the aforementioned electronic package and method, the present disclosure further comprises: disposing at least one second electronic element on the second circuit structure.

In the aforementioned electronic package and method, the present disclosure further comprises: connecting a plurality of conductive elements to an outer side of the first circuit structure.

In the aforementioned electronic package and method, after the first packaging operation is performed, an overall structure warps upward at both ends, forming a shape resembling a smiling face, wherein, during the second packaging operation, an adhesive material is applied for forming the second encapsulation layer, such that the adhesive material contracts in a direction opposite to the warping direction of the first encapsulation layer.

In the aforementioned electronic package and method, during the first packaging operation, an overall structure warps downward at both ends, forming a shape resembling a frown face, wherein, during the second packaging operation, an adhesive material is applied for forming the second encapsulation layer, such that the adhesive material contracts in a direction opposite to the warping direction of the first encapsulation layer.

As can be understood from the above, in the electronic package and the manufacturing method thereof according to the present disclosure, after forming the first encapsulation layer that encapsulates the first electronic element during the first packaging operation, the warping direction of the first encapsulation layer is determined. During the second packaging operation, the second encapsulation layer that contracts in a direction opposite to the warping direction of the first encapsulation layer is applied to mitigate the warping phenomenon of the material, thereby resolving the structural warping problems caused by the contraction of conventional packaging adhesive.

### BRIEF DESCRIPTION OF THE DRAWINGS

FIG. 1 is a schematic cross-sectional view of a conventional package-on-package structure.

FIG. 2A to FIG. 2C are schematic cross-sectional views illustrating a method of manufacturing an electronic package according to the present disclosure.

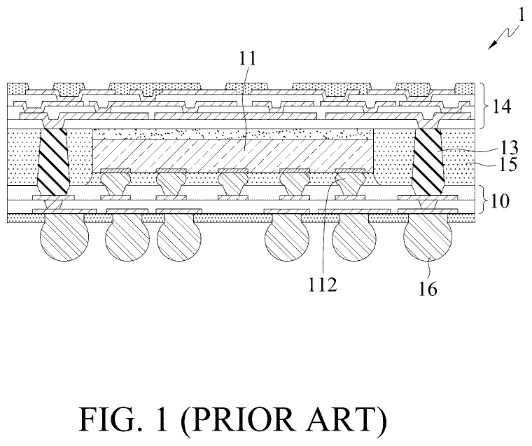

### DETAILED DESCRIPTION

Embodiments of the present disclosure are described below by examples. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes, or adjustments to the structures, ratios, or sizes are construed as falling within the scope covered by the technical contents disclosed herein. Meanwhile, terms such as “on,” “above,” “first,” “second,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

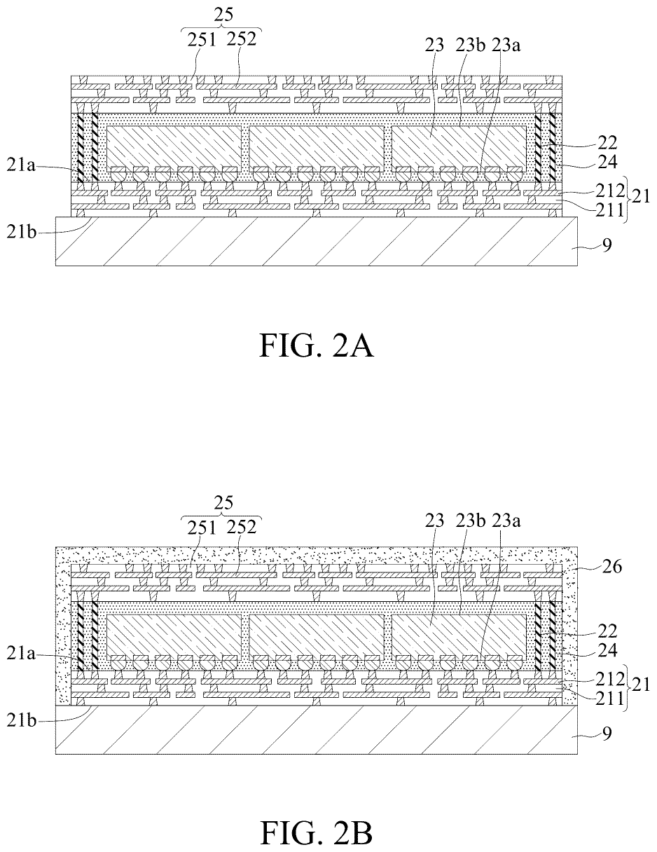

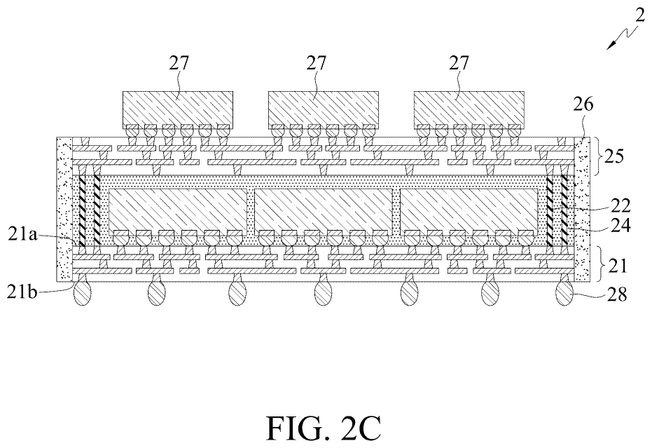

FIG. 2A to FIG. 2C are schematic cross-sectional views illustrating a method of manufacturing an electronic package 2 according to the present disclosure.

As shown in FIG. 2A, a first circuit structure 21 is formed on a carrier board 9, a plurality of conductive pillars 22 are formed on the first circuit structure 21, at least one first electronic element 23 is disposed on the first circuit structure 21, a first encapsulation layer 24 is formed on the first circuit structure 21 and encapsulates the plurality of conductive pillars 22 and the first electronic element 23, and a second circuit structure 25 is formed on the first encapsulation layer 24.

The carrier board 9 is, for example, a board body made of semiconductor material (such as silicon or glass).

The first circuit structure 21 has a first side 21a and a second side 21b opposite to the first side 21a, and the first circuit structure 21 includes at least one dielectric layer 211 and at least one routing layer 212 (e.g., a wiring layer) bonded to the dielectric layer 211, so that the first circuit structure 21 is disposed on the carrier board 9 with the second side 21b thereof. For example, the routing layer 212 is made of copper, and the dielectric layer 211 is made of polybenzoxazole (PBO), polyimide (PI), prepreg (PP), or other dielectric materials. The routing layer 212 and the dielectric layer 211 can be formed by a redistribution layer (RDL) manufacturing process.

The conductive pillars 22 can be formed on the first side 21a of the first circuit structure 21 by electroplating.

The first electronic element 23 is an active element, a passive element, or a combination of the active element and the passive element. The active element is, for example, a semiconductor chip, and the passive element is, for example, a resistor, a capacitor, or an inductor.

In an embodiment, a plurality of the first electronic elements 23 are disposed on the first circuit structure 21. The first electronic elements 23 are semiconductor chips, each having an active surface 23a and an inactive surface 23b opposite to the active surface 23a. The active surface 23a of each of the first electronic elements 23 is connected to the first side 21a of the first circuit structure 21 via a plurality of conductors.

The first encapsulation layer 24 can be formed on the first circuit structure 21 via a first packaging operation (first molding) to encapsulate the plurality of first electronic elements 23 and the plurality of conductive pillars 22. The first encapsulation layer 24 is made of insulating material, such as polyimide (PI), dry film, or epoxy (e.g., epoxy resin), but is not limited to these.

The second circuit structure 25 is formed on the first encapsulation layer 24 and is electrically connected to the plurality of conductive pillars 22. The second circuit structure 25 includes at least one dielectric layer 251 and at least one routing layer 252 (e.g., a wiring layer) bonded to the dielectric layer 251. For example, the routing layer 252 is made of copper, and the dielectric layer 251 is made of polybenzoxazole, polyimide, prepreg, or other dielectric materials. The routing layer 252 and the dielectric layer 251 can be formed by a redistribution layer manufacturing process. At this time, the thermal stress or material contraction in the aforementioned process may result in warpage.

As shown in FIG. 2B, a second packaging operation (second molding) is performed, so that a second encapsulation layer 26 is formed on the carrier board 9 and encapsulates the first circuit structure 21, the first encapsulation layer 24, and the second circuit structure 25.

In one embodiment, the warping direction is determined after the first packaging operation (forming the first encapsulation layer 24) in order to apply/select an adhesive/encapsulation material (the second encapsulation layer 26) that contracts in a direction opposite to the warping direction during the second packaging operation to mitigate warping problems. For example, if the overall structure warps upward at both ends, forming a shape resembling a smiling face after the first packaging operation, then an adhesive/encapsulation material that contracts in a direction opposite to the warping from the first packaging operation is applied during the second packaging operation. Similarly, if the overall structure warps downward at both ends, forming a shape resembling a frown face after the first packaging operation, then an adhesive/encapsulation material that contracts in a direction opposite to the warping from the first packaging operation is applied during the second packaging operation to mitigate the material's warping phenomenon.

As shown in FIG. 2C, a portion of the second encapsulation layer 26 encapsulating the second circuit structure 25 is removed, so that an upper surface of the second circuit structure 25 is exposed from the second encapsulation layer 26.

Then, a plurality of second electronic elements 27 are disposed on the second circuit structure 25, wherein each of the second electronic elements 27 is, for example, an active element, a passive element, or a combination of the active element and the passive element. The active element is, for example, a semiconductor chip, and the passive element is, for example, a resistor, a capacitor, or an inductor. In one embodiment, the second electronic elements 27 are semiconductor chips and are electrically connected to the second circuit structure 25 via a plurality of conductors in a flip-chip manner. The first encapsulation layer 24 and the second encapsulation layer 26 are formed in sequence to mitigate the warping phenomenon, so that the second electronic elements 27 can be evenly placed on the second circuit structure 25.

In addition, a plurality of conductive elements 28, such as solder bumps or solder balls (which are of Controlled Collapse Chip Connection [C4] specification), can be bonded to the second side 21b of the first circuit structure 21, so that the plurality of conductive elements 28 can be electrically connected to the routing layer 212. The warping phenomenon can be mitigated by sequentially forming the first encapsulation layer 24 and the second encapsulation layer 26, allowing the plurality of conductive elements 28 to be evenly disposed on the first circuit structure 21, thereby obtaining the electronic package 2 of the present disclosure. Subsequently, the electronic package 2 can be connected to an external device such as a circuit board via the plurality of conductive elements 28.

Through the aforementioned process, the present disclosure further provides an electronic package 2, which comprises: a first encapsulation layer 24, at least one first electronic element 23 disposed in the first encapsulation layer 24, and a second encapsulation layer 26 encapsulating the first encapsulation layer 24, wherein a contraction direction of the second encapsulation layer 26 is opposite to a warping direction of the first encapsulation layer 24.

The electronic package 2 further comprises a first circuit structure 21 disposed on one side of the first encapsulation layer 24 and a second circuit structure 25 disposed on the other side of the first encapsulation layer 24.

The electronic package 2 further comprises a plurality of conductive pillars 22 disposed in the first encapsulation layer 24 and electrically connected to the first circuit structure 21 and the second circuit structure 25.

The electronic package 2 further comprises at least one second electronic element 27 disposed on the second circuit structure 25.

The electronic package 2 further comprises a plurality of conductive elements 28 connected to an outer side of the first circuit structure 21.

In view of the above, in the electronic package and the manufacturing method thereof according to the present disclosure, after forming the first encapsulation layer that encapsulates the first electronic element during the first packaging operation, the warping direction of the first encapsulation layer is determined. During the second packaging operation, the second encapsulation layer that contracts in a direction opposite to the warping direction of the first encapsulation layer is applied to mitigate the warping phenomenon of the material, thereby resolving the structural warping problems caused by the contraction of conventional packaging adhesive.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a first encapsulation layer;
at least one first electronic element embedded in the first encapsulation layer; and
a second encapsulation layer encapsulating the first encapsulation layer, wherein a contraction direction of the second encapsulation layer is opposite to a warping direction of the first encapsulation layer.

2. The electronic package of claim 1, further comprising: a first circuit structure formed on one side of the first encapsulation layer.

3. The electronic package of claim 2, further comprising: a second circuit structure formed on the other side of the first encapsulation layer.

4. The electronic package of claim 3, further comprising: a plurality of conductive pillars formed in the first encapsulation layer and electrically connected to the first circuit structure and the second circuit structure.

5. The electronic package of claim 3, further comprising: at least one second electronic element disposed on the second circuit structure.

6. The electronic package of claim 3, further comprising: a plurality of conductive elements connected to an outer side of the first circuit structure.

7. The electronic package of claim 1, wherein, after the first encapsulation layer is formed, an overall structure warps upward at both ends, forming a shape resembling a smiling face.

8. The electronic package of claim 7, wherein the second encapsulation layer is made of an adhesive material that contracts in a direction opposite to the warping direction of the first encapsulation layer.

9. The electronic package of claim 1, wherein, after the first encapsulation layer is formed, an overall structure warps downward at both ends, forming a shape resembling a frown face.

10. The electronic package of claim 9, wherein the second encapsulation layer is made of an adhesive material that contracts in a direction opposite to the warping direction of the first encapsulation layer.

11. A method of manufacturing an electronic package, comprising:
providing at least one first electronic element;
performing a first packaging operation to form a first encapsulation layer to encapsulate the at least one first electronic element; and
performing a second packaging operation to form a second encapsulation layer to encapsulate the first encapsulation layer, wherein a contraction direction of the second encapsulation layer is opposite to a warping direction of the first encapsulation layer.

12. The method of claim 11, further comprising: forming a first circuit structure on one side of the first encapsulation layer.

13. The method of claim 12, further comprising: forming a second circuit structure on the other side of the first encapsulation layer.

14. The method of claim 13, further comprising: forming a plurality of conductive pillars electrically connected to the first circuit structure and the second circuit structure in the first encapsulation layer.

15. The method of claim 13, further comprising: disposing at least one second electronic element on the second circuit structure.

16. The method of claim 13, further comprising: connecting a plurality of conductive elements to an outer side of the first circuit structure.

17. The method of claim 11, wherein, after the first packaging operation is performed, an overall structure warps upward at both ends, forming a shape resembling a smiling face.

18. The method of claim 17, wherein, during the second packaging operation, an adhesive material is applied for forming the second encapsulation layer, such that the adhesive material contracts in a direction opposite to the warping direction of the first encapsulation layer.

19. The method of claim 11, wherein, during the first packaging operation, an overall structure warps downward at both ends, forming a shape resembling a frown face.

20. The method of claim 19, wherein, during the second packaging operation, an adhesive material is applied for forming the second encapsulation layer, such that the adhesive material contracts in a direction opposite to the warping direction of the first encapsulation layer.
